(19) United States
(12) Patent Application Publication
(10) Pub. No.: US 2003/0006489 A1
(43) Pub. Date: Jan. 9, 2003

(54) Flexible wiring substrate interposed between semiconductor element and circuit substrate

(76) Inventors: Kenzo Fujii, Tokyo (JP); Taro Hirai, Tokyo (JP)

Correspondence Address: KATTEN MUCHIN ZAVIS ROSENMAN, 575 MADISON AVENUE, NEW YORK, NY, 10022-2585, US

(21) Appl. No.: 09/900,333

(22) Filed: Jul. 6, 2001

(51) Int. Cl. H01L 23/495; H01L 23/48; H01L 23/52; H01L 29/40; H01L 21/44; H01L 21/48; H01L 21/50

(52) U.S. Cl. 257/668; 257/778; 257/738; 257/737; 438/123; 438/613; 438/108

(57) ABSTRACT

A flexible wiring substrate for coupling between a semiconductor element and a circuit substrate. The flexible wiring substrate comprises a base material layer made of insulating and flexible material, and wiring conductors formed on the base material layer. The wiring conductors are formed of at least one electroless plated layer and at least one electroplated layer formed on the at least one electroless plated layer. The wiring conductors are formed apart from a peripheral edge portion of the base material layer. A power supply line for electroplating used for forming the electroplated layer does not remain on the base material layer. The wiring conductors have, for example, a multi-layer structure comprising an electroless plated copper layer formed on the base material layer, an electroplated copper layer formed on the electroless plated copper layer, an electroplated nickel layer formed on the electroplated copper layer, and an electroplated gold layer formed on the electroplated nickel layer.

### FIELD OF THE INVENTION

The present invention relates generally to a flexible wiring substrate via which a semiconductor element is coupled with a circuit substrate. More particularly, the present invention relates to a flexible wiring substrate which is called an interposer and which is used for mounting a semiconductor element in a BGA (Ball Grid Array) type package, a CSP (Chip Size Package) and the like.

### BACKGROUND OF THE INVENTION

A conventional IC package is fabricated as follows. A semiconductor element or a silicon chip is bonded on a die pad of a lead frame. Electrodes of the silicon chip are electrically coupled to lead portions of the lead frame by wire bonding. Then, an encapsulation resin is formed to cover the silicon chip and the bonding wires. From the encapsulation resin thus formed, a number of lead portions, that is, external terminals extend toward outside in four directions. The conventional IC package of this type has a disadvantage that when the number of the external terminals is several hundreds or more, the area required for mounting the IC package becomes too large.

In order to mitigate such disadvantage, a mounting structure called a CSP (Chip Size Package) is widely used. In the CSP, first, a silicon chip is coupled onto a wiring substrate via minute conductive bumps. The wiring substrate on which the silicon chip is mounted is coupled onto a circuit substrate or circuit board via conductive bumps each having a relatively large size. The wiring substrate used in this case is also called an interposer.

It is conceivable that the silicon chip and the circuit board may be directly coupled with each other. However, such method is not feasible for the following reasons. First, a pitch of electrodes of a silicon chip and a pitch of electrodes or wiring conductors of a circuit board differ largely from each other. That is, an electrode pitch of a circuit board is considerably larger than an electrode pitch of a silicon chip. Second, it becomes difficult to ensure reliability of a silicon chip. Third, it becomes necessary to perform coupling process between the silicon chip and the circuit board in a clean room, and this causes an increase in manufacturing costs. Therefore, usually, the silicon chip is mounted on the circuit board via the wiring substrate. The present invention relates to a structure and a manufacturing method of such wiring substrate called an interposer.

FIG. 4 is a cross sectional view showing an example of a conventional mounting structure. In FIG. 4, a semiconductor element or silicon chip 41 is coupled onto a wiring substrate 43 via minute conductive bumps 42. Also, the wiring substrate 43 is coupled onto a circuit board 45 via conductive bumps 44 having relatively large size. The wiring substrate 43 comprises an insulating base material layer 43b and wiring conductor portions 43a formed on the insulating base material layer 43b. The conductive bumps 42 couple between electrodes not shown in the drawing of the silicon chip 41 and the wiring conductor portions 43a of the wiring substrate 43. The conductive bumps 44 couple between wiring conductors of the wiring substrate 43 and wiring or circuit patterns 45a of the circuit board 45. Therefore, as shown in FIG. 4, the wiring conductor portions 43a function as repeaters or repeating conductors and, thereby, electric circuits are formed from the silicon chip 41 to the circuit board 45, via the minute conductive bumps 42, the wiring conductor portions 43a and the larger conductive bumps 44. In this way, the silicon chip 41 and the circuit board 45 are electrically coupled.

FIG. 5A is a plan view of the mounting structure of FIG. 4. FIG. 5B is a partial enlarged cross sectional view schematically showing a conventional wiring substrate 43 used in the mounting structure shown in FIG. 4. In FIG. 5A, for the sake of easy understanding, illustration of the circuit board 45 is omitted, an outer circumference portion of the silicon chip 41 is shown by a dotted line, and a structure under the silicon chip 41 is shown by perspective representation.

As shown in FIG. 5A, a pitch of end portions of the wiring conductors 43a which couple with the larger conductive bumps 44 is larger than that of other end portions of the wiring conductors 43a which couple with the minute conductive bumps 42. The pitch of the end portions of the wiring conductors 43a which couple with the minute conductive bumps 42 corresponds to a pitch of electrodes of the silicon chip 41. The pitch of the end portions of the wiring conductors 43a which couple with the larger conductive bumps 44 corresponds to a pitch of wiring patterns of the circuit board 45. The silicon chip 41 is coupled with the wiring conductors 43a of the wiring substrate 43 via the minute conductive bumps 42, and the wiring conductors 43a of the wiring substrate 43 are coupled with the circuit board 45 via the larger conductive bumps 44.

By interposing the wiring substrate 43 in this way, it is possible to convert the small electrode pitch of the silicon chip 41, which is approximately 100 μm, into the large electrode pitch of the wiring patterns of the circuit board 45 which is approximately 300 μm. Thereby, it becomes possible to accommodate the silicon chip 41 which has the electrode pitch of approximately 100 μm to the circuit board 45 which has the wiring pitch of approximately 300 μm. Therefore, it is possible to electrically couple the silicon chip 41 with the circuit board 45 easily and reliably.

As shown in FIG. 5B, the conventional wiring substrate 43 comprises the flexible base material layer 43b which is made of polyimide and which has a thickness of 125 μm, and wiring conductors 43a which are formed on the base material layer 43b. Therefore, the wiring substrate 43 is a flexible wiring substrate. Each of the wiring conductors 43a has a multi-layer structure comprising, from the side of the polyimide base material layer 43b, an adhesive layer 43c, a copper layer 43d having a thickness of 18 μm, a nickel layer 43e having a thickness of 2 μm, and a gold layer 43f having a thickness of 1 μm. Here, the copper layer 43d functions as a main current path. The nickel layer 43e functions to prevent material of the gold layer 43f from diffusing into the copper layer 43d. The gold layer 43f is formed to prevent the copper layer 43d and the nickel layer 43e from being oxidized and to ensure reliable connection between the conductive bumps 42 and the wiring conductors 43a and between the conductive bumps 44 and the wiring conductors 43a. Among conventional wiring substrates, there is a wiring substrate in which wiring conductors are made only of copper. However, the surface of a copper layer is easily oxidized. Therefore, the wiring substrate having the wiring conductors made only of copper is suitable for a usual printed circuit board in which flux can be used, but is not suitable for a wiring substrate for the CSP in which such flux can not be used.

With reference to FIG. 6A and FIG. 6B, an explanation will be made on a method of manufacturing a conventional wiring substrate 43. FIG. 6A is a plan view showing a condition of the wiring substrate 43 during a process of manufacturing thereof. FIG. 6B is a schematic partial enlarged cross sectional view of the wiring substrate 43 shown in FIG. 6A.

First, a base material layer 43b made of polyimide is prepared. Then, on whole surface of the base material layer 43b, a copper foil having a thickness of 18 μm, that is, a copper layer 43d, is adhered via an adhesive layer 43c. On the copper layer 43d, by using photolithography, photoresist patterns are formed which correspond to patterns of the wiring conductors 43a to be formed and which are not shown in the drawing. The photoresist patterns has, in addition to the pattern portions corresponding to the wiring conductors 43a, pattern portions corresponding to a plated frame 43g which is located around the wiring conductors 43a, and pattern portions corresponding to plated power supply lines 43h which couple between the plated frame 43g and the wiring conductors 43a. Thereafter, portions of the copper layer 43d which are not covered by the photoresist patterns are removed by etching. The photoresist patterns are then removed. Thereby, patterns of the copper layer 43d including the pattern portions corresponding to the wiring conductors 43a, the plated frame 43g and the plated power supply lines 43h are formed.

Next, a power source for plating not shown in the drawing is connected to the plated frame 43g. Then, on the patterned copper layer 43d, a nickel layer 43e and a gold layer 43f are sequentially formed by electroplating. The plan view of FIG. 6A and the cross sectional view of FIG. 6B show the wiring substrate in this condition. Lastly, the plated frame 43g around the wiring conductors 43a together with the portion of the base material layer 43b under the plated frame 43g are cut away and removed. Thereby, the conventional wiring substrate 43 shown in FIGS. 5A and 5B is completed. As shown in FIGS. 5A and 5B, in the fabricated wiring substrate 43, the plated power supply lines 43h are remained on the base material layer 43b and around the wiring conductors 43a.

In the above-mentioned prior art, the nickel layer 43e is formed by electroplating. The reasons why the nickel layer 43e is not formed by using electroless plating is as follows. Electroless nickel plating solution or liquid which is practically used always includes phosphorus or boron. As is well known, phosphorus or boron gives an influence on characteristics of a silicon chip, even when the quantity of the phosphorus or boron is small. When the silicon chip 41 is mounted on the wiring substrate 43, the wiring substrate 43 exists very close to the silicon chip 41. Therefore, if the wiring conductor 43a includes an electroless nickel plated layer, there is a possibility that the characteristics of the silicon chip 41 is deteriorated by phosphorus or boron contained in the electroless nickel plated layer, and it becomes impossible to ensure reliability of the silicon chip 41. Thus, it is necessary that the nickel layer 43e is always formed by electroplating. As a result, it is inevitable that the power supply lines 43h for electroplating remain at the peripheral portion of the conventional wiring substrate 43 after completion thereof.

The above-mentioned conventional wiring substrate 43 which is also called a subtractive wiring substrate has the following disadvantages. First, the lower limit of a feasible thickness of a copper foil is approximately 18 μm. Therefore, the lower limit of a thickness of the copper layer 43d becomes approximately 18 μm. However, since the thickness of the copper layer 43d of 18 g m is too thick, it is impossible to form very minute wiring conductors required in a wiring substrate of an IC having a high integration degree. Thus, the above-mentioned conventional wiring substrate 43 is not suitable for an IC having a high integration degree. Second problem of the conventional wiring substrate is that the plated power supply lines 43h remain in the peripheral portion of the wiring substrate 43. There is a possibility that the plated power supply lines 43h function as antennas which radiate and/or receive noises. Especially, when the above-mentioned conventional wiring substrate 43 is used as a wiring substrate for an IC used in a high frequency application, such problem becomes prominent.

In order to solve the problems of the conventional subtractive wiring substrate, there is proposed a fulladditive wiring substrate. However, the conventional fulladditive wiring substrate has low productivity. Also, in order to fabricate the conventional fulladditive wiring substrate, it is necessary to use a solution for electroless nickel plating which contain phosphorus or boron. As mentioned above, the electroless plated nickel layer which contains phosphorus or boron deteriorates reliability of a silicon chip and is not preferable. Further, the conventionally proposed manufacturing process for the fulladditive wiring substrate may include expensive dry process such as sputtering, ion plating or the like. Therefore, manufacturing costs become high.

### SUMMARY OF THE INVENTION

Therefore, it is an object of the present invention to obviate the above-mentioned problems of the conventional flexible wiring substrate and method of manufacturing the same.

It is another object of the present invention to provide a flexible wiring substrate and a method of manufacturing the same in which very minute wiring conductors can be easily formed.

It is still another object of the present invention to provide a flexible wiring substrate which can be appropriately used as a wiring substrate for a high frequency IC and a method of manufacturing such flexible wiring substrate.

It is still another object of the present invention to provide a flexible wiring substrate which does not deteriorate reliability of a semiconductor element mounted thereon and a method of manufacturing such flexible wiring substrate.

It is still another object of the present invention to provide a flexible wiring substrate and a method of manufacturing the same in which manufacturing costs can be lowered.

In order to solve the problems of the conventional subtractive wiring substrate and the conventional additive wiring substrate, the flexible wiring substrate according to the present invention is fabricated as follows. First, a surface of an insulating base material layer is roughened and a thin electroless plated copper layer is formed on the surface. Photoresist patterns are formed on the electroless plated copper layer such that portions of the electroless plated copper layer on which no wiring patterns are to formed are covered by the photoresist patterns and such that portions of the electroless plated copper layer on which wiring patterns are to be formed are exposed. Then, by using the electroless plated copper layer as a power supply line and a plating electrode, a relatively thick electroplated copper layer and protective plated layer or layers are sequentially formed on the exposed portions of the electroless plated copper layer. The protective plated layers may comprise, for example, an electroplated nickel layer and an electroplated gold layer. Then, the photoresist patterns are removed, and portions of the electroless plated copper layer exposed thereby are removed.

In the flexible wiring substrate fabricated in this way, the thickness of the copper layer can be 10 μm or smaller. Therefore, it is possible to form very minute wiring conductors. Also, power supply lines used for plating do not remain in the fabricated flexible wiring substrate. Thus, antennas for radiating and/or receiving noises do not exist. As a result, the flexible wiring substrate according to the present invention is especially preferable as a wiring substrate of an IC used in a high frequency application. Further, the nickel layer is an electroplated nickel layer which is formed by electroplating. Therefore, the nickel layer does not contain phosphorus or boron, and reliability of a semiconductor element is not deteriorated thereby.

Also, in the manufacturing method of the flexible wiring substrate according to the present invention, the surface of the insulating base material layer is roughened before the process of plating. Therefore, the adhesion strength between the insulating base material layer and the electroless plated copper layer becomes high. Thus, in the flexible wiring substrate according to the present invention, it is possible to surely prevent the wiring conductors from coming off the insulating base material layer. Further, although the flexible wiring substrate according to the present invention is a semiadditive wiring substrate, expensive dry process such as sputtering, ion plating or the like is not required to fabricate the flexible wiring substrate. Therefore, manufacturing costs can be lowered.

According to an aspect of the present invention, there is provided a flexible wiring substrate comprising: a base material layer which is made of insulating and flexible material; and wiring conductors formed on said base material layer, said wiring conductors comprising at least one electroless plated layer and at least one electroplated layer formed on said at least one electroless plated layer.

In this case, it is preferable that the wiring conductors are formed apart from a peripheral edge of the base material layer.

It is also preferable that conductive portions functioned as a power supply line for electroplating which is used for forming the at least one electroplated layer do not remain on the base material layer.

It is further preferable that the wiring conductors have a multi-layer structure comprising an electroless plated copper layer formed on the base material layer, an electroplated copper layer formed on the electroless plated copper layer, and a layer which may be any one layer selected from a group consisting of an electroplated gold layer, an electroplated silver layer, an electroplated tin layer and an electroplated palladium layer and which is formed on the electroplated copper layer.

It is advantageous that the wiring conductors have a multi-layer structure comprising an electroless plated copper layer formed on the base material layer, an electroplated copper layer formed on the electroless plated copper layer, an electroplated nickel layer formed on the electroplated copper layer, and a layer which may be any one layer selected from a group consisting of an electroplated gold layer, an electroplated silver layer, an electroplated tin layer and an electroplated palladium layer and which is formed on the electroplated nickel layer.

It is also advantageous that a surface of the base material layer is roughened, and the wiring conductors are formed on the roughened surface of the base material layer.

According to another aspect of the present invention, there is provided a mounting structure of a semiconductor device comprising: a flexible wiring substrate having a base material layer which is made of insulating and flexible material, and wiring conductors formed on the base material layer, the wiring conductors comprising at least one electroless plated layer and at least one electroplated layer formed on the at least one electroless plated layer; a semiconductor element mounted on the flexible wiring substrate via first conductive bumps, the semiconductor element having a plurality of electrodes, each of the plurality of electrodes being coupled with a corresponding one of the wiring conductors via one of the first conductive bumps; and a circuit substrate on which the flexible wiring substrate is mounted via the second conductive bumps and which has circuit pattern portions on at least one surface thereof, each of the wiring conductors coupled with the plurality of electrodes of the semiconductor element via the first conductive bumps being coupled with a corresponding one of the circuit pattern portions, via one of the second conductive bumps, and each of the second conductive bumps being larger than one of the first conductive bumps; wherein each of the plurality of electrodes of the semiconductor element is electrically coupled with a corresponding one of the circuit pattern portions of the circuit substrate, via one of the first conductive bumps, corresponding one of the wiring conductors of the flexible wiring substrate, and one of the second conductive bumps.

In this case, it is preferable that the wiring conductors of the flexible wiring substrate are formed apart from a peripheral edge of the base material layer.

It is also preferable that a power supply line for electroplating which is used for forming the at least one electroplated layer does not remain on the base material layer.

According to still another aspect of the present invention, there is provided a method of manufacturing a flexible wiring substrate comprising: preparing a base material layer which is made of insulating and flexible material; forming an electroless plated layer on a surface of the base material layer by electroless plating; forming a resist layer for electroplating which has predetermined patterns on the electroless plated layer; forming, by electroplating, at least one electroplated layer on portions of the electroless plated layer which are exposed via opening portions of the resist layer, by using the electroless plated layer as a power supply line for electroplating and as a plating electrode; removing the resist layer having the predetermined patterns; and removing portions of the electroless plated layer which are exposed by the removing the resist layer having the predetermined patterns, portions of the electroless plated layer remaining on the base material layer and the at least one electroplated layer on the electroless plated layer forming wiring conductors.

In this case, it is preferable that the method further comprises, before forming an electroless plated layer on a surface of the base material layer, roughening a surface of the base material layer, and wherein in the forming an electroless plated layer on a surface of the base material layer, the electroless plated layer is formed on the roughened surface of the base material layer.

It is also preferable that, wherein, in the forming an electroless plated layer on a surface of the base material layer, the electroless plated layer is formed on whole area of the surface of the base material layer.

It is further preferable that the forming a resist layer for electroplating which has predetermined patterns on the electroless plated layer comprises: forming a resist layer on whole area of the electroless plated layer, the resist layer being resistant to plating solution used in the forming at least one electroplated layer; and selectively removing the resist layer such that portions on which wiring conductors are to be formed are exposed, thereby the resist layer having the predetermined patterns being formed on the electroless plated layer.

It is advantageous that, in the removing portions of the electroless plated layer which are exposed by the removing the resist layer having the predetermined patterns, the exposed portions of the electroless plated layer are removed by etching, and portions of the at least one electroplated layer and the electroless plated layer covered by the at least one electroplated layer remain on the base material layer.

It is also advantageous that, in the forming at least one electroplated layer, portions of electroless plated layer which are exposed via opening portions of the resist layer having the predetermined patterns function as a plating electrode for electroplating, and portions of the electroless plated layer which are covered by the resist layer having the predetermined patterns function as a power supply line for electroplating.

It is further advantageous that, in the removing portions of the electroless plated layer which are exposed by the removing the resist layer having the predetermined patterns, portions of the electroless plated layer which functioned as a power supply line for electroplating are removed, thereby conductor portions which functioned as a power supply line for electroplating do not remain on the base material layer.

It is preferable that the electroless plated layer is an electroless plated copper layer, and the at least one electroplated layer comprises an electroplated copper layer formed on the electroless plated copper layer, and a layer which may be any one layer selected from a group consisting of an electroplated gold layer, an electroplated silver layer, an electroplated tin layer and an electroplated palladium layer and which is formed on the electroplated copper layer.

It is also preferable that the electroless plated layer is an electroless plated copper layer, and the at least one electroplated layer comprises an electroplated copper layer formed on the electroless plated copper layer, an electroplated nickel layer formed on the electroplated copper layer, and a layer which may be any one layer selected from a group consisting of an electroplated gold layer, an electroplated silver layer, an electroplated tin layer and an electroplated palladium layer and which is formed on the electroplated nickel layer.

According to still another aspect of the present invention, there is provided a method of manufacturing a flexible wiring substrate comprising: preparing a base material layer which is made of insulating and flexible material; roughening a surface of the base material layer; forming an electroless plated layer on whole area of the roughened surface of the base material layer by electroless plating; forming a photoresist layer on whole area of the electroless plated layer; selectively removing the photoresist layer such that portions of the electroless plated layer on which wiring conductors are to be formed and a part of a peripheral portion of the electroless plated layer are exposed; coupling an exposed portion at the peripheral portion of the electroless plated layer with a power supply for electroplating; forming, by electroplating, at least one electroplated layer on exposed portions of the electroless plated layer on which wiring conductors are to be formed, wherein a current from the power supply is supplied to the exposed portion at the peripheral portion of the electroless plated layer and to the exposed portions of the electroless plated layer on which wiring conductors are to be formed via the portions of the electroless plated layer covered by the photoresist layer, and wherein the exposed portions of the electroless plated layer on which wiring conductors are to be formed function as a plating electrode; removing the photoresist layer; and removing, by etching, portions of the electroless plated layer which are exposed by the removing the photoresist layer and the exposed portions at a peripheral portion of the electroless plated layer, wherein portions of the electroless plated layer remaining on the base material layer and the at least one electroplated layer on the electroless plated layer form wiring conductors.

In this case, it is preferable that the electroless plated layer is an electroless plated copper layer, and the at least one electroplated layer comprises an electroplated copper layer formed on the electroless plated copper layer, an electroplated nickel layer formed on the electroplated copper layer, and a layer which may be any one layer selected from a group consisting of an electroplated gold layer, an electroplated silver layer, an electroplated tin layer and an electroplated palladium layer and which is formed on the electroplated nickel layer.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIG. 1A is a plan view showing a flexible wiring substrate according to an embodiment of the present invention;

FIG. 1B is a schematic partial enlarged cross sectional view of the flexible wiring substrate of FIG. 1A;

FIG. 2A through FIG. 2E are schematic partial enlarged cross sectional views showing conditions of the flexible wiring substrate shown in FIG. 1A and FIG. 1B during a manufacture thereof;

FIG. 3A through FIG. 3D are also schematic partial enlarged cross sectional views showing conditions of the flexible wiring substrate shown in FIG. 1A and FIG. 1B during manufacture thereof;

FIG. 4 is a cross sectional view showing an example of a conventional mounting structure for a semiconductor element;

FIG. 5A is a plan view showing the conventional mounting structure of FIG. 4;

FIG. 5B is a partial enlarged cross sectional view schematically showing a conventional wiring substrate used in the mounting structure shown in FIG. 4;

FIG. 6A is a plan view showing a condition of the conventional wiring substrate during a process of manufacturing thereof; and

FIG. 6B is a schematic partial enlarged cross sectional view of the conventional wiring substrate shown in FIG. 6A.

### DESCRIPTION OF A PREFERRED EMBODIMENT

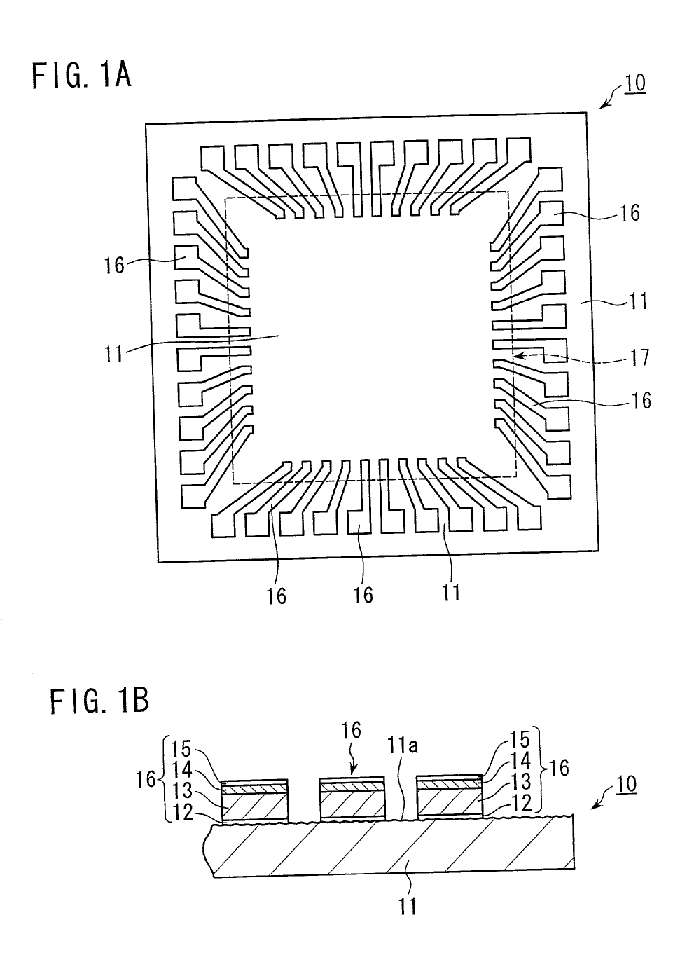

With reference to the drawings, embodiments of the present invention will now be described. FIG. 1A is a plan view showing a flexible wiring substrate according to an embodiment of the present invention. FIG. 1B is a schematic partial enlarged cross sectional view of the flexible wiring substrate of FIG. 1A.

The wiring substrate or flexible wiring substrate 10 shown in FIG. 1A and FIG. 1B comprises an insulating base material layer 11, which is made of flexible material, and wiring conductors 16 formed on the insulating base material layer 11. The thickness of the insulating base material layer 11 is, for example, 125 μm. The insulating base material layer 11 is made, for example, of polyimide. In place of polyimide, it is possible to use, for example, liquid crystal polymer material as material of the insulating base material layer 11. A typical example of the liquid crystal polymer material is aromatic polyester.

One of the surfaces of the insulating base material layer 11 is roughened, and the wiring conductors 16 are formed on the roughened surface 11a. Each of the wiring conductors 16 has a multi-layer structure. Each of the wiring conductors 16 comprises, from the side of the insulating base material layer 11, an electroless plated copper layer 12 having a thickness of, for example, approximately 0.5 μm, an electroplated copper layer 13 having a thickness of, for example, approximately 10 μm, an electroplated nickel layer 14 having a thickness of, for example, approximately 2 μm, and an electroplated gold layer 15 having a thickness of, for example, approximately 1 μm. In FIG. 1A, an outside shape and location of a semiconductor element or a silicon chip 17 which is to be mounted on the flexible wiring substrate 10 is schematically shown by a dotted line. The flexible wiring substrate 10 according to the present embodiment corresponds to a wiring substrate called an interposer on which a semiconductor element is mounted and which is coupled with a circuit substrate or circuit board.

When compared with the conventional flexible wiring substrate, the flexible wiring substrate 10 according to the present embodiment has the following merits. First, the thickness of the electroplated copper layer 13 is approximately 10 μm and is considerably thin. Therefore, it becomes possible to form very minute wiring conductors. Thus, it is possible to preferably use the flexible wiring substrate 10 according to the present embodiment as a wiring substrate for an IC device having a high integration degree. It is possible to make the thickness of the electroplated copper layer 13 still thinner if necessary. For example, it is possible to make the thickness of the electroplated copper layer 13 to approximately 5 μm. Since the electroplated copper layer 13 is formed by using electroplating, it is possible to easily control the thickness of the electroplated copper layer 13 to a desired value, and it is also possible to make the thickness of the electroplated copper layer 13 thinner than that of the copper foil used in the conventional flexible wiring substrate.

Second, as shown in FIG. 1A, conductive portions which function as a power supply line for electroplating do not remain on the insulating base material layer 11 and around the wiring conductors 16. That is, unlike the conventional wiring substrate, antennas for radiating and/or receiving noises do not exist. Therefore, the flexible wiring substrate 10 according to the present embodiment is especially preferable as a wiring substrate of an IC used in a high frequency application.

Third, the nickel layer 14 is an electroplated nickel layer which is formed by electroplating. Unlike the electroless plated nickel layer, the electroplated nickel layer 14 does not contain phosphorus or boron. Therefore, even when the silicon chip 17 is mounted on the flexible wiring substrate 10, reliability of the silicon chip 17 is not deteriorated thereby.

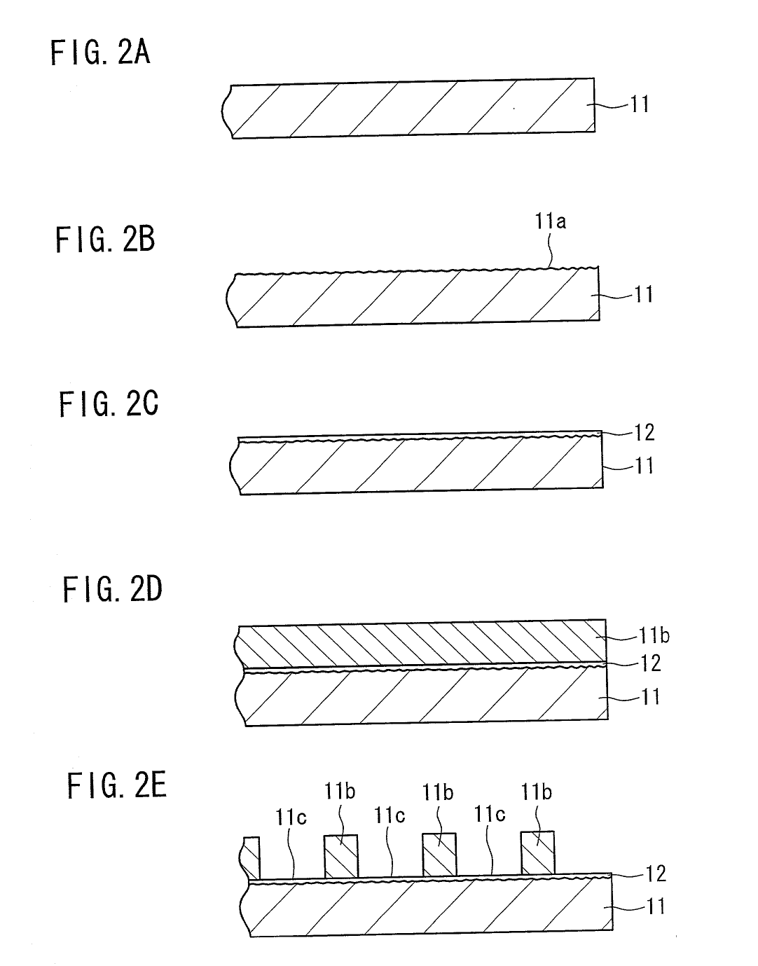

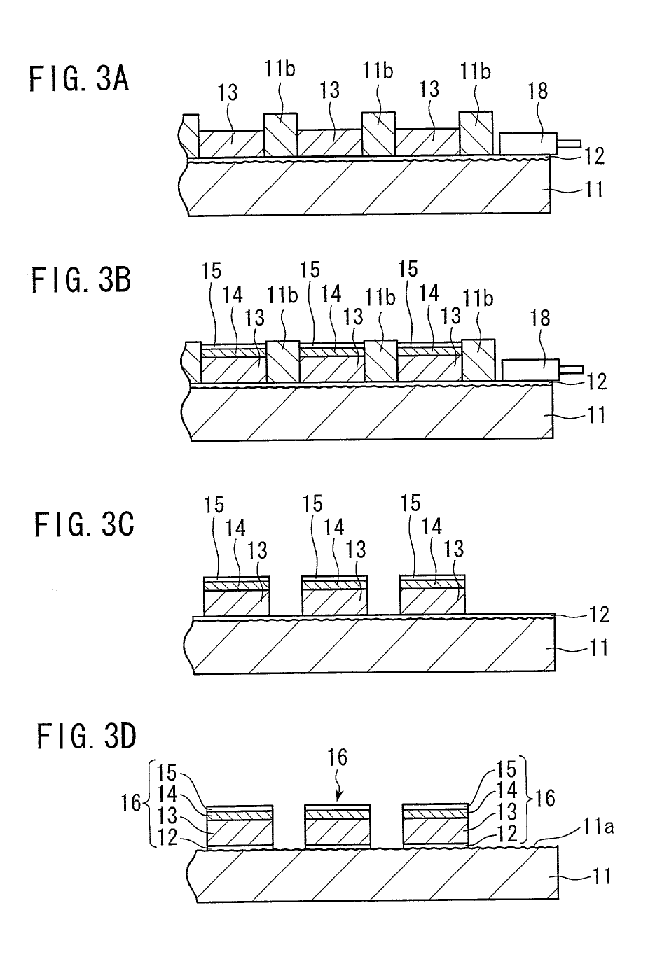

An explanation will now be made on a method of manufacturing a flexible wiring substrate according to the present embodiment. FIG. 2A through FIG. 2E and FIG. 3A through FIG. 3C are schematic partial enlarged cross sectional views showing conditions of the flexible wiring substrate 10 according to the present embodiment during manufacture thereof.

First, as shown in FIG. 2A, an insulating base material layer 11 made of polyimide and the like is prepared. The insulating base material layer 11 has the sizes, for example, of 70 mm by 100 mm, and has a thickness, for example, of 125 μm.

As shown in FIG. 2B, one of the surfaces of the insulating base material layer 11 is roughened, for example, by wet blasting. The wet blasting is a method of roughening a surface of the insulating base material layer 11 in which high pressure liquid mixed with abrasive grains and high pressure air are simultaneously blasted onto the surface of the insulating base material layer 11. The liquid is, for example, water. Thereby, a roughened surface 11a of the insulating base material layer 11 is formed. The wet blasting is performed, for example, in the following conditions.

Abrasive grains: abrasive grains each having a polygonal shape and having a Knoop hardness of 2000 and average grain size of 0.2 mm,

Concentration of abrasive grains: 25%,

Pressure of the liquid: 100 KPa (KiloPascal), and

Pressure of air: 150 KPa.

An example of an average roughness of the roughened surface 11a of the insulating base material layer 11 is 0.2 μm. The reasons why the surface of the insulating base material layer 11 is roughened in this embodiment are as follows. If the electroless copper plating mentioned later is performed on the surface of the insulating base material layer 11 without roughening the surface, adhesive strength between the electroless plated copper layer and the insulating base material layer 11 becomes relatively low. In such case, there is a possibility that the electroless plated copper layer is easily peeled off the insulating base material layer 11. However, when the surface of the insulating base material layer 11 is w previously roughened as in the present embodiment, the electroless plated copper layer is inlaid into uneven potions of the roughened surface 11a of the insulating base material layer 11. By anchoring effect provided by such structure, it becomes possible to tightly adhere the electroless plated copper layer to the insulating base material layer 11. Therefore, during a process thereafter, the electroless plated copper layer does not peel off the insulating base material layer 11.

Next, palladium catalyst is applied on the roughened surface 11a of the insulating base material layer 11. The insulating base material layer 11 is soaked in a plating solution stored in a plating solution bath not shown in the drawing for a predetermined time. Thereby, as shown in FIG. 2C, by electroless plating which uses the palladium catalyst as nuclei or seeds, a electroless plated copper layer 12 having a thickness of, for example, 0.5 μm is formed on whole portion of the roughened surface 11a of the insulating base material layer 11.

As shown in FIG. 2D, a resist film or film resist 11b having a thickness of, for example, 100 μm is formed or laminated on the surface of the electroless plated copper layer 12. As a material for the resist film 11b, a material having a tolerance to plating solution used in an electroplating process mentioned later can be used. An example of the resist film 11b is a photoresist film.

Next, as shown in FIG. 2E, the resist film 11b is patterned by using photolithography. That is, portions of the resist film 11b on portions 11c of the electroless plated copper layer 12 on which wiring conductors are to be formed later are removed to partially expose the electroless plated copper layer 12 via openings of the resist film 11b. Also, portion or portions of the resist film 11b on peripheral portions of the electroless plated copper layer 12 are removed to partially expose the electroless plated copper layer 12. In this case, it is not necessary to expose all of the peripheral portion of the electroless plated copper layer 12, but it is only necessary to expose a part of the peripheral portion of the electroless plated copper layer 12.

As shown in FIG. 3A, a terminal or terminals 18 for electroplating are coupled to the portions of the electroless plated copper layer 12 which expose on the peripheral portions of the insulating base material layer 11. The terminals 18 are connected to a power source for electroplating not shown in the drawing. Then, although not shown in the drawing, the insulating base material layer 11 is soaked in plating solution stored in a plating solution bath such that the exposed portions 11c of the electroless plated copper layer 12 on which wiring conductors are to be formed are located in the plating solution. In this case, the terminals 18 and portions of the electroless plated copper layer 12 to which the terminals 18 are coupled are disposed outside the plating solution. In the plating solution, there are disposed one or more electrodes which oppose to the electroless plated copper layer 12 and which function as an anode. Then, a predetermined voltage is applied between the electroless plated copper layer 12 and the electrodes which should function as the anode by using a power source coupled to the terminals 18 for a predetermined time. Thereby, as shown in FIG. 3A, by electroplating, the electroplated copper layer 13 having a thickness of, for example, 10 μm is formed on the surfaces of the exposed portions 11c of the electroless plated copper layer 12.

In this process of electroplating, the electroless plated copper layer 12 is used as a plating electrode for the electroplating, that is, as a cathode. The electroplated copper layer 13 is formed on portions of the electroless plated copper layer 12 which function as the plating electrode, that is, on the exposed portions of the electroless plated copper layer 12. Also, in this electroplating process, a current for electroplating flows from the terminals 18 through the electroless plated copper layer 12 to the plating solution. In this way, the electroless plated copper layer 12 is used not only as the plating electrode but also as a power supply line for electroplating. This is one of the characteristic features of the present embodiment. In this case, the power supply line for electroplating means a conductor portion on the insulating base material layer which conducts a current for electroplating to the plating electrode.

The thickness of the electroplated copper layer 13 can be thinner than the thickness value mentioned above, if necessary. For example, the thickness can be approximately 5 μm. Since the electroplated copper layer 13 is formed by electroplating, it is possible to easily control the thickness of the electroplated copper layer 13 to a desired value, and to make the thickness of the electroplated copper layer 13 thinner than that of the copper foil used in the conventional flexible wiring substrate.

Next, as shown in FIG. 3B, an electroplated nickel layer 14 having a thickness of, for example, 2 μm is formed on the surface of the electroplated copper layer 13 by electroplating. Further, by electroplating, an electroplated gold layer 15 having a thickness of, for example, 1 μm is formed on the surface of the electroplated nickel layer 14. The process of forming the electroplated nickel layer 14 and the process of forming the electroplated gold layer 15 are substantially the same as the process of forming the electroplated copper layer 13 mentioned above and, therefore, detailed explanation thereof is omitted here. However, the plating solution used in each of the processes differs from each other. Also, similarly to the process of forming the electroplated copper layer 13, in the process of forming the electroplated nickel layer 14 and in the process of forming the electroplated gold layer 15, a current for electroplating flows from the terminals 18 via the electroless plated copper layer 12 to the plating solution.

As shown in FIG. 3C, the terminals 18 are removed. Then, the resist film 11b remaining on the electroless plated copper layer 12 is removed. In this condition, wiring conductor portions comprising the electroless plated copper layer 12, the electroplated copper layer 13, the electroplated nickel layer 14, and the electroplated gold layer 15 are electrically short-circuited via the electroless plated copper layer 12. Therefore, it is necessary to remove portions of the electroless plated copper layer 12 which exist between the wiring conductors. This is done by removing the exposed portions of the electroless plated copper layer 12 by etching. By this process, as shown in FIG. 3D, the portions of the electroless plated copper layer 12 which exist between the wiring conductors 16 are removed by etching and, at the same time, portions of the electroless plated copper layer 12 to which the terminals 18 were coupled before are also removed by etching. That is, unnecessary portions of the electroless plated copper layer 12 are all removed by one common etching process. As a result, conductive portions which functioned as the power supply line for electroplating are removed from the surface of the insulating base material layer 11. This is also one of the characteristic features of the manufacturing method of the flexible wiring substrate according to the present embodiment.

FIG. 3D is a schematic partial enlarged cross sectional view of a flexible wiring substrate showing a condition the portions of the electroless plated copper layer 12 between the wiring conductors 16 are removed by etching. The flexible wiring substrate of FIG. 3D corresponds to the completed flexible wiring substrate 10 according to the present embodiment shown in FIGS. 1A and 1B. In the flexible wiring substrate 10 according to the present embodiment fabricated in this way, conductor portions which functioned as the power supply line for electroplating do not remain on the insulating base material layer 11. Thus, antennas for radiating and/or receiving noises do not exist. Therefore, the flexible wiring substrate 10 according to the present embodiment is especially suitable for a wiring substrate of an IC used in a high frequency application.

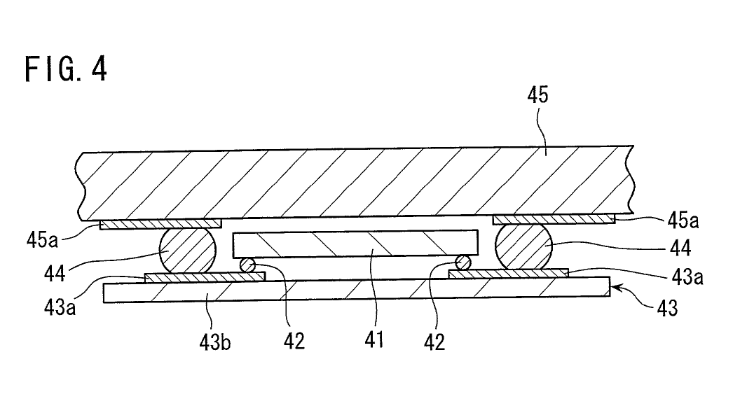

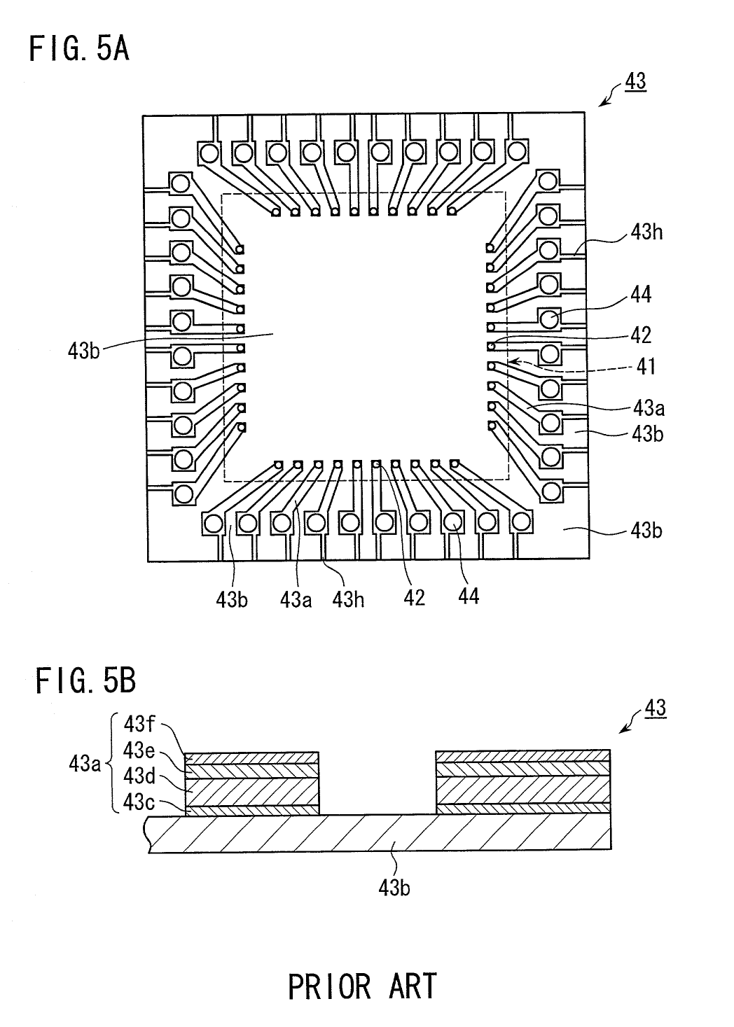

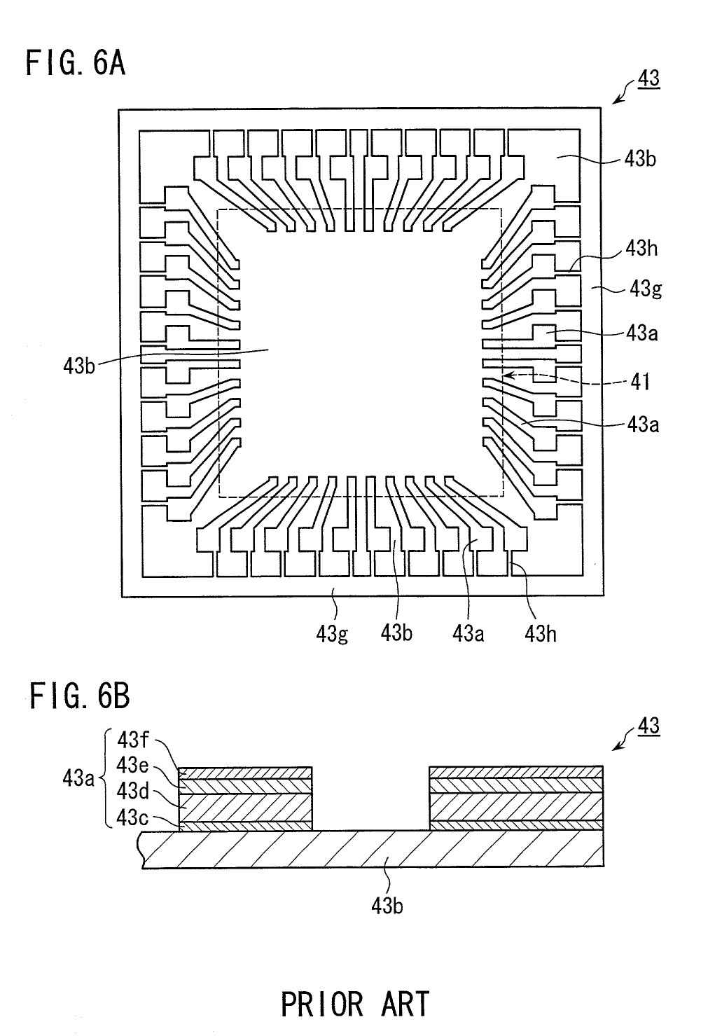

The flexible wiring substrate 10 fabricated in this way can be used, for example, in a structure similar to the conventional structure shown in FIG. 4. That is, a semiconductor element or a silicon chip is mounted on the flexible wiring substrate 10. Electrodes of the semiconductor element are coupled with the wiring conductors 16 of the flexible wiring substrate 10 via minute conductive bumps. The flexible wiring substrate 10 on which the semiconductor element is mounted is coupled with a circuit board. In this case, the wiring conductors 16 of the flexible wiring substrate 10 are coupled with circuit patterns of the circuit board via relatively large conductive bumps. Thereby, the semiconductor element is electrically coupled with the circuit board. The flexible wiring substrate 10 according to the present embodiment can be used as a wiring substrate called an interposer which is used in a BGA (Ball Grid Array) type package, a CSP (Chip Size Package), and the like.

In the above-mentioned flexible wiring substrate 10 according to the present embodiment, the wiring conductors 16 has a four layer structure comprising the electroless plated copper layer 12 formed on the insulating base material layer 11, the electroplated copper layer 13 formed on the electroless plated copper layer 12, the electroplated nickel layer 14 formed on the electroplated copper layer 13, and electroplated gold layer 15 formed on the electroplated nickel layer 14. Here, the electroplated copper layer 13 functions as the main current path of a current for electroplating. The electroplated nickel layer 14 functions as a layer for preventing material of the electroplated gold layer 15 from diffusing into the electroplated copper layer 13. The electroplated gold layer 15 prevents the electroless plated copper layer 12, the electroplated copper layer 13 and the electroplated nickel layer 14 from being oxidized, and ensures reliable coupling between conductive bumps not shown in the drawing and the wiring conductors 16.

The wiring conductors 16 may have other structures different from the structure mentioned above. For example, it is possible to omit formation of the electroplated nickel layer 14, so that the wiring conductors 16 may have a three layer structure comprising the electroless plated copper layer 12 formed on the insulating base material layer 11, the electroplated copper layer 13 formed on the electroless plated copper layer 12, and electroplated gold layer 15 formed on the electroplated copper layer 12. In this case, it is possible to decrease the number of manufacturing process steps and to shorten the manufacturing time. However, in order to prevent all the material of the electroplated gold layer from diffusing into the electroplated copper layer, it is necessary to make the thickness of the electroplated gold layer relatively large.

Alternatively, the wiring conductors 16 may have a four layer structure comprising the electroless plated copper layer 12 formed on the insulating base material layer 11, the electroplated copper layer 13 formed on the electroless plated copper layer 12, the electroplated nickel layer 14 formed on the electroplated copper layer 13, and a layer which may be any one layer selected from a group consisting of an electroplated silver layer, an electroplated tin layer and an electroplated palladium layer and which is formed on the electroplated nickel layer 14. Portions of the uppermost layer of the wiring conductors are coupled with conductive bumps. Thus, it is possible to select the material of the uppermost layer of wiring conductors depending on the material of the conductive bumps which are coupled with the wiring conductors. Therefore, this structure is used in case the electroplated silver layer, the electroplated tin layer or the electroplated palladium layer is preferred to the electroplated gold layer.

It is also possible to omit formation of the electroplated nickel layer 14, so that the wiring conductors 16 may have a three layer structure comprising the electroless plated copper layer 12 formed on the insulating base material layer 11, the electroplated copper layer 13 formed on the electroless plated copper layer 12, and a layer which may be any one layer selected from a group consisting of an electroplated silver layer, an electroplated tin layer and an electroplated palladium layer and which is formed on the electroplated copper layer 13. In this case, it is possible to decrease the number of manufacturing process steps and to shorten the manufacturing time. However, in order to prevent all the material of the layer which may be any one layer selected from the group consisting of the electroplated silver layer, the electroplated tin layer and the electroplated palladium layer from diffusing into the electroplated copper layer, it is necessary to make the thickness of the layer which may be any one layer selected from the group consisting of the electroplated silver layer, the electroplated tin layer and the electroplated palladium layer relatively large.

According to the present invention, it is possible to make the thickness of the wiring conductors thinner than that of the conventional wiring conductors. Especially, it is possible to make the thickness of the copper layer of the wiring conductors relatively thin, for example, 10 μm or smaller. Therefore, it is possible to form very minute wiring conductors. Also, since the power supply lines for electroplating do not remain in the completed flexible wiring substrate, antennas for radiating and/or receiving noises do not exist. Therefore, the flexible wiring substrate according to the present invention is especially suitable for a wiring substrate of an IC used in a high frequency application. Further, the nickel layer of the wiring conductors consists of a nickel layer formed by electroplating. Thus, the nickel layer does not contain phosphorus and boron, so that a semiconductor element mounted on the flexible wiring substrate does not undergo bad influence caused thereby. Therefore, reliability of the semiconductor element can be improved. Still further, although the flexible wiring substrate according to the present invention is a semiadditive wiring substrate, the flexible wiring substrate according to the present invention can be manufactured not by using expensive dry process such as sputtering and ion plating but by using economical plating process. Thereby, manufacturing costs of the flexible wiring substrate can be decreased.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as fall within the scope of the appended claims.

What is claimed is:

1. A flexible wiring substrate comprising:
a base material layer which is made of insulating and flexible material; and
wiring conductors formed on said base material layer, said wiring conductors comprising at least one electroless plated layer and at least one electroplated layer formed on said at least one electroless plated layer.

2. A flexible wiring substrate as set forth in claim 1, wherein said wiring conductors are formed apart from a peripheral edge of said base material layer.

3. A flexible wiring substrate as set forth in claim 1, wherein conductive portions functioned as a power supply line for electroplating which is used for forming said at least one electroplated layer do not remain on said base material layer.

4. A flexible wiring substrate as set forth in claim 1, wherein said wiring conductors have a multi-layer structure comprising an electroless plated copper layer formed on said base material layer, an electroplated copper layer formed on said electroless plated copper layer, and a layer which may be any one layer selected from a group consisting of an electroplated gold layer, an electroplated silver layer, an electroplated tin layer and an electroplated palladium layer and which is formed on said electroplated copper layer.

6. A flexible wiring substrate as set forth in claim 1, wherein said wiring conductors have a multi-layer structure comprising an electroless plated copper layer formed on said base material layer, an electroplated copper layer formed on said electroless plated copper layer, an electroplated nickel layer formed on said electroplated copper layer, and a layer which may be any one layer selected from a group consisting of an electroplated gold layer, an electroplated silver layer, an electroplated tin layer and an electroplated palladium layer and which is formed on said electroplated nickel layer.

6. A flexible wiring substrate as set forth in claim 1, wherein a surface of said base material layer is roughened, and said wiring conductors are formed on the roughened surface of said base material layer.

7. A mounting structure of a semiconductor device comprising:
a flexible wiring substrate having a base material layer which is made of insulating and flexible material, and wiring conductors formed on said base material layer, said wiring conductors comprising at least one electroless plated layer and at least one electroplated layer formed on said at least one electroless plated layer;
a semiconductor element mounted on said flexible wiring substrate via first conductive bumps, said semiconductor element having a plurality of electrodes, each of said plurality of electrodes being coupled with a corresponding one of said wiring conductors via one of said first conductive bumps; and
a circuit substrate on which said flexible wiring substrate is mounted via said second conductive bumps and which has circuit pattern portions on at least one surface thereof, each of said wiring conductors coupled with said plurality of electrodes of said semiconductor element via said first conductive bumps being coupled with a corresponding one of said circuit pattern portions, via one of said second conductive bumps, and each of said second conductive bumps being larger than one of said first conductive bumps;
wherein each of said plurality of electrodes of said semiconductor element is electrically coupled with a corresponding one of said circuit pattern portions of said circuit substrate, via one of said first conductive bumps, corresponding one of said wiring conductors of said flexible wiring substrate, and one of said second conductive bumps.

8. A mounting structure of a semiconductor device as set forth in claim 7, wherein said wiring conductors of said flexible wiring substrate are formed apart from a peripheral edge of said base material layer.

9. A mounting structure of a semiconductor device as set forth in claim 7, wherein a power supply line for electroplating which is used for forming said at least one electroplated layer does not remain on said base material layer.

10. A method of manufacturing a flexible wiring substrate comprising:
preparing a base material layer which is made of insulating and flexible material;
forming an electroless plated layer on a surface of said base material layer by electroless plating;
forming a resist layer for electroplating which has predetermined patterns on said electroless plated layer;
forming, by electroplating, at least one electroplated layer on portions of said electroless plated layer which are exposed via opening portions of said resist layer, by using said electroless plated layer as a power supply line for electroplating and as a plating electrode;
removing said resist layer having said predetermined patterns; and
removing portions of said electroless plated layer which are exposed by said removing said resist layer having said predetermined patterns, portions of said electroless plated layer remaining on said base material layer and said at least one electroplated layer on said electroless plated layer forming wiring conductors.

11. A method of manufacturing a flexible wiring substrate as set forth in claim 10, further comprising, before forming an electroless plated layer on a surface of said base material layer, roughening a surface of said base material layer, and wherein in said forming an electroless plated layer on a surface of said base material layer, said electroless plated layer is formed on the roughened surface of said base material layer.

12. A method of manufacturing a flexible wiring substrate as set forth in claim 10, wherein, in said forming an electroless plated layer on a surface of said base material layer, said electroless plated layer is formed on whole area of said surface of said base material layer.

13. A method of manufacturing a flexible wiring substrate as set forth in claim 10, wherein said forming a resist layer for electroplating which has predetermined patterns on said electroless plated layer comprises:
forming a resist layer on whole area of said electroless plated layer, said resist layer being resistant to plating solution used in said forming at least one electroplated layer; and
selectively removing said resist layer such that portions on which wiring conductors are to be formed are exposed, thereby said resist layer having said predetermined patterns being formed on said electroless plated layer.

14. A method of manufacturing a flexible wiring substrate as set forth in claim 10, wherein, in said removing portions of said electroless plated layer which are exposed by said removing said resist layer having said predetermined patterns, the exposed portions of said electroless plated layer are removed by etching, and portions of said at least one electroplated layer and said electroless plated layer covered by said at least one electroplated layer remain on said base material layer.

15. A method of manufacturing a flexible wiring substrate as set forth in claim 10, wherein, in said forming at least one electroplated layer, portions of electroless plated layer which are exposed via opening portions of said resist layer having said predetermined patterns function as a plating electrode for electroplating, and portions of said electroless plated layer which are covered by said resist layer having said predetermined patterns function as a power supply line for electroplating.

16. A method of manufacturing a flexible wiring substrate as set forth in claim 10, wherein, in said removing portions of said electroless plated layer which are exposed by said removing said resist layer having said predetermined patterns, portions of said electroless plated layer which functioned as a power supply line for electroplating are removed, thereby conductor portions which functioned as a power supply line for electroplating do not remain on said base material layer.

17. A method of manufacturing a flexible wiring substrate as set forth in claim 10, wherein said electroless plated layer is an electroless plated copper layer, and said at least one electroplated layer comprises an electroplated copper layer formed on said electroless plated copper layer, and a layer which may be any one layer selected from a group consisting of an electroplated gold layer, an electroplated silver layer, an electroplated tin layer and an electroplated palladium layer and which is formed on said electroplated copper layer.

18. A method of manufacturing a flexible wiring substrate as set forth in claim 10, wherein said electroless plated layer is an electroless plated copper layer, and said at least one electroplated layer comprises an electroplated copper layer formed on said electroless plated copper layer, an electroplated nickel layer formed on said electroplated copper layer, and a layer which may be any one layer selected from a group consisting of an electroplated gold layer, an electroplated silver layer, an electroplated tin layer and an electroplated palladium layer and which is formed on said electroplated nickel layer.

19. A method of manufacturing a flexible wiring substrate comprising:
preparing a base material layer which is made of insulating and flexible material;
roughening a surface of said base material layer;
forming an electroless plated layer on whole area of said roughened surface of said base material layer by electroless plating;
forming a photoresist layer on whole area of said electroless plated layer;
selectively removing said photoresist layer such that portions of said electroless plated layer on which wiring conductors are to be formed and a part of a peripheral portion of said electroless plated layer are exposed;
coupling an exposed portion at the peripheral portion of said electroless plated layer with a power supply for electroplating;
forming, by electroplating, at least one electroplated layer on exposed portions of said electroless plated layer on which wiring conductors are to be formed, wherein a current from said power supply is supplied to said exposed portion at the peripheral portion of said electroless plated layer and to said exposed portions of said electroless plated layer on which wiring conductors are to be formed via the portions of said electroless plated layer covered by said photoresist layer, and wherein said exposed portions of said electroless plated layer on which wiring conductors are to be formed function as a plating electrode;
removing said photoresist layer; and
removing, by etching, portions of said electroless plated layer which are exposed by said removing said photoresist layer and said exposed portions at a peripheral portion of said electroless plated layer, wherein portions of said electroless plated layer remaining on said base material layer and said at least one electroplated layer on said electroless plated layer form wiring conductors.

20. A method of manufacturing a flexible wiring substrate as set forth in claim 19, wherein said electroless plated layer is an electroless plated copper layer, and said at least one electroplated layer comprises an electroplated copper layer formed on said electroless plated copper layer, an electroplated nickel layer formed on said electroplated copper layer, and a layer which may be any one layer selected from a group consisting of an electroplated gold layer, an electroplated silver layer, an electroplated tin layer and an electroplated palladium layer and which is formed on said electroplated nickel layer.
